(19) United States
(12) Patent Application Publication
(10) Pub. No.: US 2024/0402258 A1
(43) Pub. Date: Dec. 5, 2024

(54) METHODS, SYSTEMS, ARTICLES OF MANUFACTURE AND APPARATUS TO MANAGE BATTERY OUTGASSING CONDITIONS

(71) Applicant: Intel Corporation, Santa Clara, CA (US)

(72) Inventors: A Ezekiel Poulose, Kerala (IN); Avinash Manu Aravindan, Kerala (IN); Naoki Matsumura, San Jose, CA (US); Jagadish Vasudeva Singh, Bangalore (IN)

(21) Appl. No.: 18/328,490

(22) Filed: Jun. 2, 2023

(51) Int. Cl. G01R 31/392; G01R 31/389; H01M 10/48; H02J 7/00

(52) U.S. Cl. CPC G01R 31/392; G01R 31/389; H01M 10/48; H02J 7/00712; H01M 4/661; H01M 4/663; H01M 4/667; H01M 10/0413; H01M 10/0431

(57) ABSTRACT

Systems, apparatus, articles of manufacture, and methods are disclosed to manage battery outgassing conditions. An example apparatus includes an enclosure having a first conductive surface located proximate to an outer boundary of the enclosure, a second conductive surface located a first distance from the first conductive surface, a capacitance circuit coupled to the first conductive surface and the second conductive surface, and a charge control circuit to control an input signal to the second conductive surface and a third conductive surface based on an output of the capacitance circuit.

### FIELD OF THE DISCLOSURE

This disclosure relates generally to battery management and, more particularly, to methods, systems, articles of manufacture and apparatus to manage battery outgassing conditions.

### BACKGROUND

In recent years, a demand for battery-powered devices has increased. While battery-powered devices have long been present in wireless telephones and laptops, additional devices such as smart watches and wireless security cameras have become increasingly present. In some circumstances, wireless security cameras are not proximate to hardwired line voltage and, as such, charging techniques are employed to keep such devices charged to enable proper device functionality.

### BRIEF DESCRIPTION OF THE DRAWINGS

FIG. 1A is a structural diagram of an example pouch-type stacked cell battery that may be monitored by examples disclosed herein to manage outgassing conditions.

FIG. 1B is a structural diagram of an example cylindrical battery structure that may be monitored by examples disclosed herein to manage outgassing conditions.

FIG. 2A is a layer diagram of an example layered portion of a battery in which outgassing is not occurring.

FIG. 2B is a layer diagram of an example layered portion of a battery in which outgassing is occurring.

FIG. 3A is a cross-sectional diagram of an example battery in which outgassing is not occurring.

FIG. 3B is a cross-sectional diagram of an example battery in which outgassing is occurring.

FIG. 3C is a plot of an example multiplying factor corresponding to outgassing deflection.

FIG. 4 is a block diagram of an example environment in which an example battery management system (BMS) monitors a battery to manage outgassing conditions.

FIG. 5 is a block diagram of the example BMS of FIG. 4 to manage outgassing conditions.

FIG. 6 is a flowchart representative of example machine readable instructions and/or example operations that may be executed, instantiated, and/or performed by example programmable circuitry to implement the battery management system of FIG. 5.

FIG. 7 is a block diagram of an example processing platform including programmable circuitry structured to execute, instantiate, and/or perform the example machine readable instructions and/or perform the example operations of FIG. 6 to implement the battery management system of FIG. 5.

FIG. 8 is a block diagram of an example implementation of the programmable circuitry of FIG. 7.

FIG. 9 is a block diagram of another example implementation of the programmable circuitry of FIG. 7.

FIG. 10 is a block diagram of an example software/firmware/instructions distribution platform (e.g., one or more servers) to distribute software, instructions, and/or firmware (e.g., corresponding to the example machine readable instructions of FIG. 6) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s). In some examples, programmable circuitry disclosed herein may reside in one or more local environment, remote environments (e.g., cloud computing environments), and/or combinations thereof.

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Batteries are used in many devices, particularly mobile devices such as laptops, smartphones, wearables (e.g., smartwatches), etc. To accommodate operational demands of such devices, particular types of batteries are utilized that have charge densities and recharge cycle count capabilities to survive an expected lifetime of the devices with which they provide power. In some examples, Lithium-ion (Li-ion) and/or Lithium Polymer (Li—Po) batteries are utilized in view of their relatively high charge density and recharge cycle count capabilities.

While batteries with relatively high charge densities and relatively high recharge cycle count capabilities are favorable characteristics, such batteries exhibit particular drawbacks. In particular, rechargeable batteries exhibit battery swell that is caused by a generation of gasses, referred to herein as “outgassing.” Battery swell, as used herein, refers to a physical deformity of a battery structure that is caused by outgassing pressure. The physical deformity may cause an increase in a physical length, width and/or diameter of a battery. In some examples, the increased physical dimensions are relatively minor when they do not interfere with one or more structural aspects of the device in which it operates. In some examples, the increased physical dimensions caused by outgassing are substantial when they not only interfere with one or more structural aspects of the device in which it operates but force particular structural deviation and/or damage to the device itself. In addition to battery swell causing device damage, battery swell caused by outgassing phenomenon creates an increased fire hazard. Generally speaking, circumstances in which battery outgassing occurs is considered a degree of failure of the battery.

As rechargeable batteries age, outgassing typically increases in frequency and severity (e.g., larger structural displacements occur during outgassing occurrences). Factors that aggregate outgassing occurrences include temperature conditions (e.g., relatively warmer battery environments tend to increase the chances of outgassing occurrences) and particular (e.g., fast) charging modes by respective battery charging circuitry. Early detection of battery swell has the potential to mitigate battery failures and/or otherwise mitigate the impact of damage to the battery itself and/or the device in which the battery operates. Existing techniques to detect battery swell suffer from any such detection occurring after substantial physical deformation occurs, which is too late to instantiate protective and/or preventative measures that could otherwise extend the operating life of the battery and/or prevent physical damage to the device in which the battery operates.

Examples disclosed herein include a battery management system (BMS) to detect battery swell occurrences and, when detected, augment, alter and/or otherwise cause the charging circuitry to operate in an alternate manner in an effort to extend the operational life of the battery and avoid device damage. In some examples, the BMS, the battery and/or the enclosure that houses the battery includes mounting hardware and/or structural features to support the enclosure within a device, such as within the device being powered by the battery (e.g., a wireless telephone). Alternate operating modes facilitated by examples disclosed herein include, but are not limited to, reduced charge current mode(s), reduced termination voltage(s), reduced charge duration mode(s), time-slice charge duration mode(s) to permit the battery to cool prior to subsequent charge activity, etc. Examples disclosed herein enable detection of battery swelling occurrences before significant physical deformation starts. Additionally, examples disclosed herein enable outgassing detection without the addition of battery components or layers, except for a single wire (e.g., a conductive lead) attached to a conductive layer (e.g., a layer having a conductive inner side and a non-conductive (e.g., protective) outer side) of the battery. Stated differently, examples disclosed herein do not require new/additional hardware modifications that impose a cost barrier to implementation.

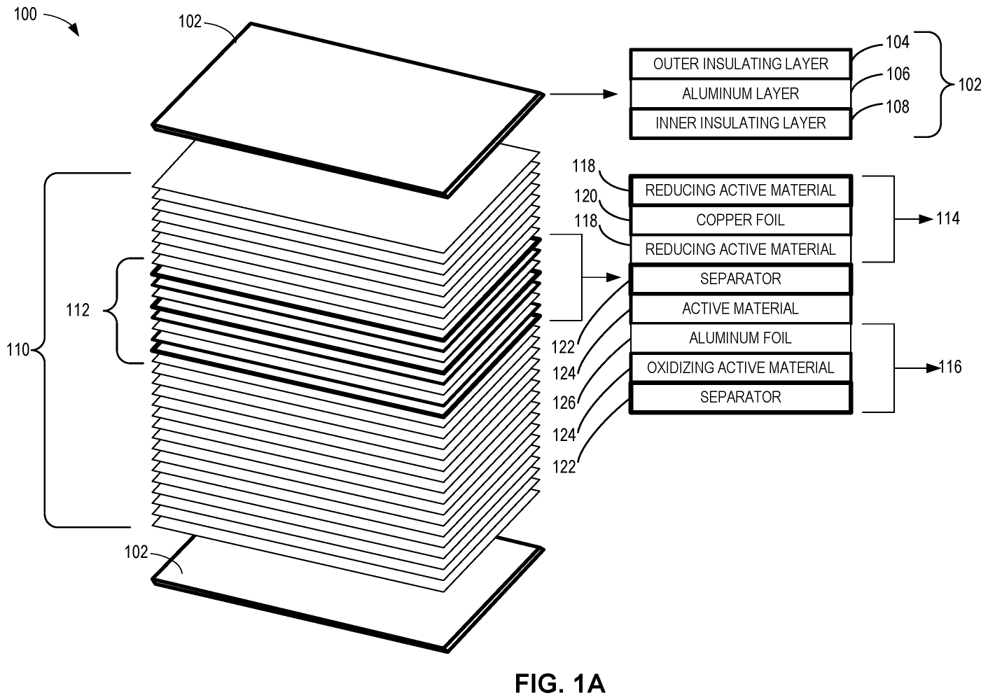

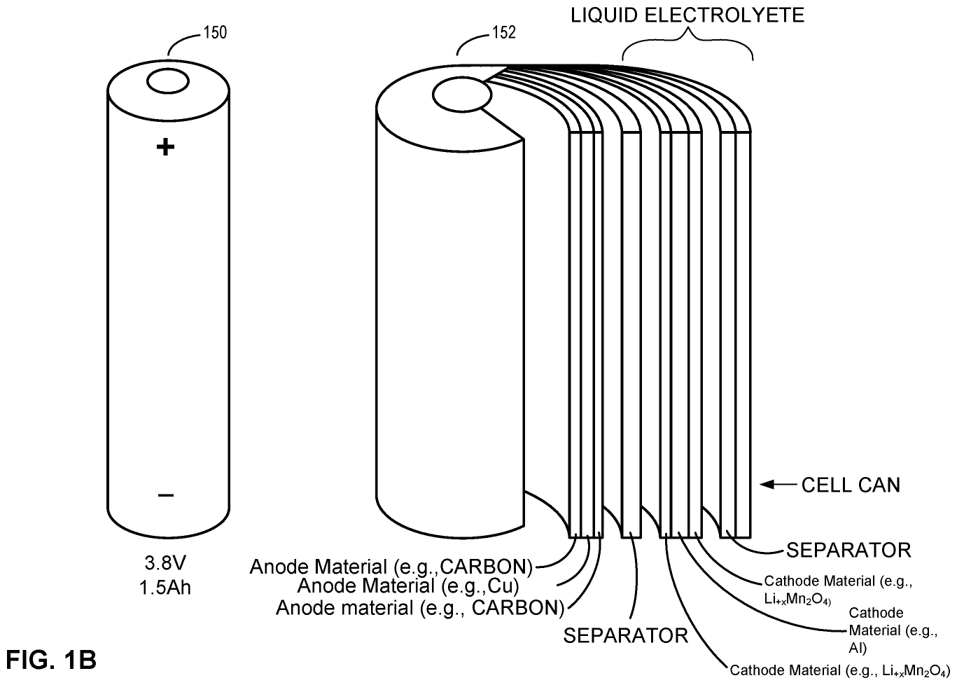

FIG. 1A is a structural diagram (block diagram) of an example pouch-type stacked cell battery 100. In the illustrated example of FIG. 1A, the battery 100 includes a pouch layer 102 (e.g., an external sheath, an external housing, an enclosure of the battery 100) that is made up of three example sub layers. In particular, the example pouch layer 102 includes an outer insulating layer 104, an aluminum layer 106, and an inner insulating layer 108. The illustrated example of FIG. 1A includes the pouch layer 102 proximate to a top side of the battery 100 as well another pouch layer 102 at a bottom side of the battery 100. While the illustrated example of FIG. 1A shows separate portions of the example pouch layer 102 at a top and bottom side of the battery 100, the example pouch layer may be a continuous material layer that surrounds the entirety of the example battery 100. In some examples, the battery 100 has an orthogonal cubic shape with six sides, each covered with an example pouch layer 102.

The example battery 100 of FIG. 1A also includes any number of internal layers 110, some of which are active battery layers 112 that include materials to enable energy storage. In the illustrated example of FIG. 1A, the active battery layers 112 include an anode 114 and a cathode 116 that are separated by an example separator layer 122. As shown in the illustrated example of FIG. 1A, the anode 114 and the cathode 116 include any number of sub-layers therein. The example anode 114 includes example reducing active layers 118 (e.g., reducing active material, such as graphite) that surround an example copper foil layer 120. The example cathode 116 includes example oxidizing active material layers 124 surrounding an example aluminum foil layer 126. While the illustrated example of FIG. 1A includes particular layers, particular materials of layers and a particular quantity of layers, examples disclosed herein are not limited thereto. Examples disclosed herein may include any other type of material that enables energy storage. Additionally, examples disclosed herein are not limited to the example orthogonal cubic structure of FIG. 1A, but may include cylindrical arrangements and/or any other form factor. For instance, FIG. 1B illustrates a structural diagram of an example cylindrical battery structure 150. FIG. 1B also illustrates an example exploded view of the cylindrical battery structure 152 that includes any number of layers and corresponding materials capable of energy storage. In some examples, the cylindrical battery 150, 152 is referred to as a jelly-rolled structure. In still other examples, flat jelly-rolled structures are implemented without limitation. Further descriptions of examples disclosed herein relate to the example pouch structure of FIG. 1A for purposes of convenience and not limitation.

Examples disclosed herein take advantage of capacitive characteristics exhibited by a battery structure to determine whether outgassing is occurring and a magnitude of such outgassing phenomena. In particular, examples disclosed herein capture, identify and/or otherwise detect capacitive characteristics based on the example aluminum layer 106 of the external sheath 102 and one of the example anode 114 or cathode 116 of FIG. 1A. Stated differently, electrodes between the aluminum layer 106 and the anode 114 or electrodes between the aluminum layer 106 and the cathode 116 essentially form a parallel plate capacitor. In some examples, electodes between the anode 114 and the cathode 116 may be used to acquire capacitance values of the battery. A capacitance value corresponding to this parallel plate capacitor depends on an overlapping surface area of separated layers (A), a dielectric constant of any medium between the separated layers (K₁), a permittivity of free space (ε₀), and a spacing between the separated layers (d₁). In particular, the capacitance value may be determined in a manner consistent with example Equation 1.

$$C = \frac{{ε}_{0} {K}_{1} A}{{d}_{1}} . \qquad Equation 1$$

In the illustrated example of Equation 1, as the distance (d₁) increases due to outgassing, a corresponding capacitance (C) value decreases.

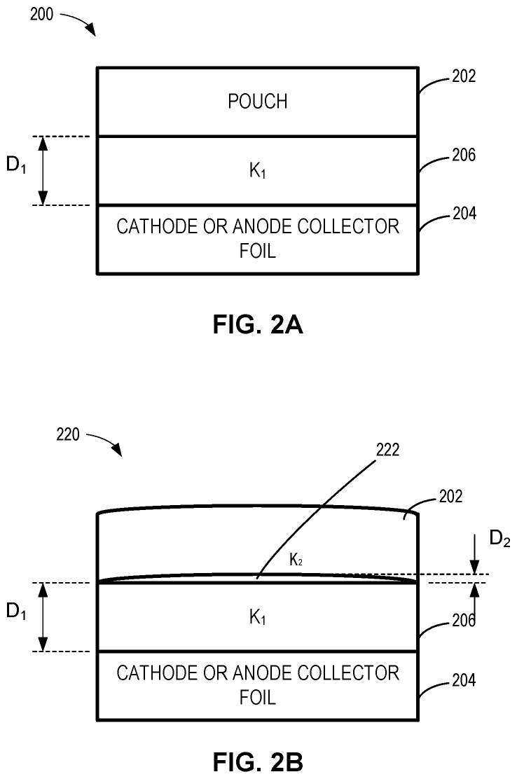

FIG. 2A is a layer diagram of an example layered portion of a battery 200 in which outgassing is not occurring. In the illustrated example of FIG. 2A, the battery 200 includes a pouch layer 202, a cathode layer 204 and an intermediary layer 206. The example intermediary layer 206 is associated with a first distance value (d₁) when outgassing activity is not occurring. FIG. 2B is a layer diagram of an example layered portion of a battery 220 in which outgassing is occurring. The example battery 220 of FIG. 2B has the same pouch layer 202, cathode layer 204 and intermediary layer 206 as is shown in FIG. 2A. However, the illustrated example of FIG. 2B also illustrates an outgassing layer 222 that forms during one or more charge cycles of the battery 220. The example outgassing layer 222 is associated with a second distance value (d₂) and a second dielectric constant (K₂). During an outgassing process, generated gasses get trapped inside one or more layers of the battery 220 to form the outgassing layer(s) 222, which effectively adds a new layer to the battery 220 that was not present at the time of manufacture. Pressure caused by this gas generation causes the pouch to swell outwards, which increases a distance between the plates (e.g., the pouch layer 202 and the cathode layer 204). The effective distance that results from such outgassing activity is the original distance value of the intermediary layer (d₁) and the distance value formed by the outgassing pressure (d₂). In effect, the outgassing shown in the illustrated example of FIG. 2B causes an increased physical dimension and a decreased capacitance value.

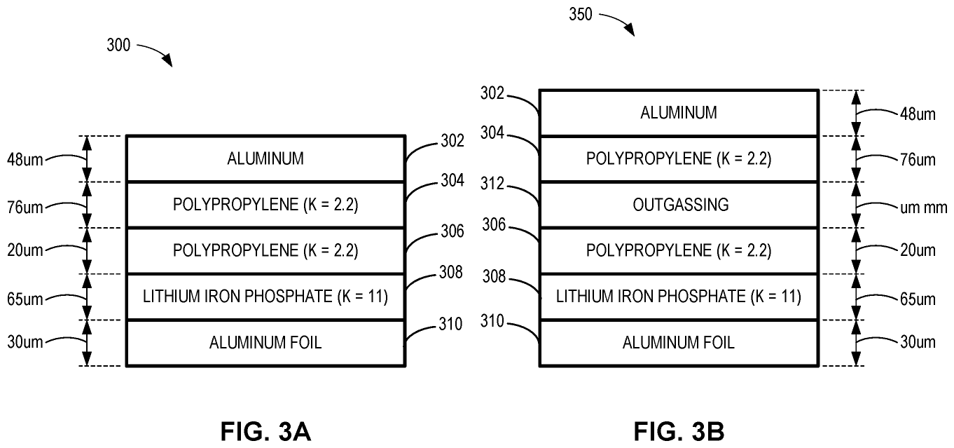

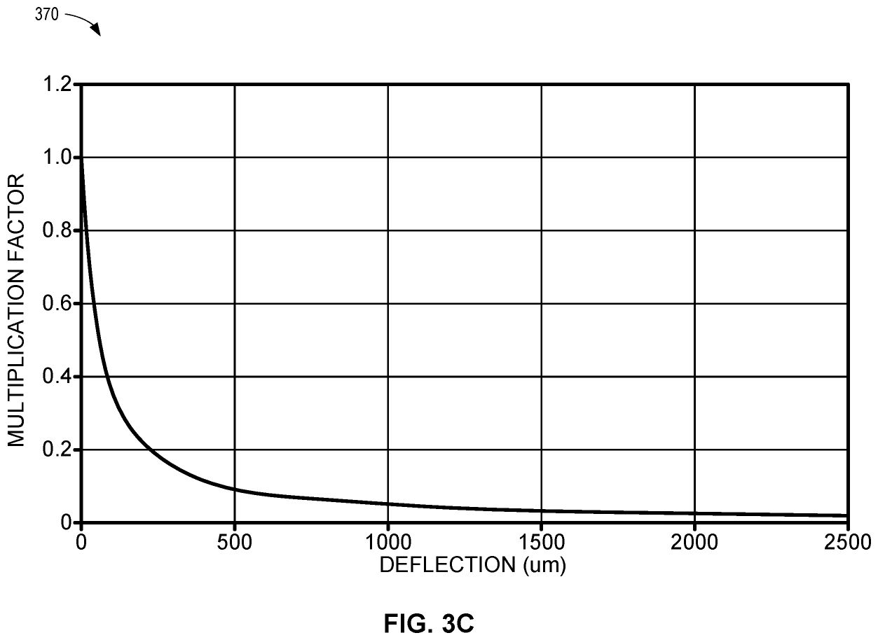

FIGS. 3A and 3B are cross-sectional views of battery layers. In particular, FIG. 3A is a cross-sectional view of a battery without outgassing 300 and FIG. 3B is a cross-sectional view of a battery with outgassing 350. The example non-outgassing battery 300 and the example outgassing battery 350 include an example pouch metal layer 302 constructed with aluminum having a thickness of 48 um, an example pouch insulation layer 304 constructed with polypropylene having a thickness of 76 um and a dielectric constant of 2.2, an example separator layer 306 constructed with polypropylene having a thickness of 20 um and a dielectric constant of 2.2, an example cathode active layer 308 constructed with lithium iron phosphate having a thickness of 65 um and a dielectric constant of 11, and an example cathode current collector layer 310 constructed with aluminum foil having a thickness of 30 um. While particular layer thicknesses and material types are shown in the illustrated example of FIGS. 3A and 3B, such examples are provided for demonstration purposes and not limitation. Other thicknesses and/or material types may be considered with examples disclosed herein.

Contrary to the illustrated example of FIG. 3A in which the example battery 300 is not exhibiting outgassing activity, the example battery 350 of FIG. 3B is exhibiting outgassing activity and includes an additional outgassing layer 312. Outgassing in the illustrated example of FIG. 3B is shown as having a uniform thickness and the gas type may be CO₂ with a dielectric constant of 1.1. In other examples, layers may have varying thicknesses and outgassing may involve gasses other than CO₂. Generally speaking, the illustrated examples of FIGS. 3A and 3B exhibit properties of a parallel plate capacitor with multiple series dielectrics. An effective dielectric constant (k_{eff}) and an effective capacitance value (C_{eff}) with two series dielectric constants and thicknesses as k1, d1 and k2, d2, respectively, and area A between plates is determined in a manner consistent with example Equation 2 and Equation 3.

$${k}_{eff} = \frac{{K}_{1} {K}_{2} ( {d}_{1} + {d}_{2} )}{{K}_{2} {d}_{1} + {K}_{1} {d}_{2}} \qquad Equation 2$$

$${C}_{eff} = \frac{{ε}_{0} {K}_{1} {K}_{2} A}{{K}_{2} {d}_{1} + {K}_{1} {d}_{2}} \qquad Equation 3$$

In view of example Equation 2 and Equation 3 above, the effective capacitance value in a normal condition (e.g., an initial condition after manufacture) is determined in a manner consistent with example Equation 4.

$${C}_{initial} = \frac{{ε}_{0} {K}_{normal} A}{{d}_{normal}} \qquad Equation 4$$

In the illustrated example of Equation 4, Kₙₒᵣₘₐₗ is the effective dielectric constant in a normal (e.g., new) state and dₙₒᵣₘₐₗ is the spacing between plates in a normal state/condition (e.g., no outgassing occurring). An example capacitance value after outgassing may be determined in a manner consistent with example Equation 5.

$${C}_{Outgas} = \frac{{C}_{initial} * 1}{1 + \frac{{K}_{normal} {d}_{delta}}{{K}_{outgas} {d}_{normal}}} \qquad Equation 5$$

In the illustrated example of Equation 5, K_{outgas} is the dielectric constant of the gas and d_{delta} is the change in spacing (deflection) between plates due to swelling.

An example capacitance change due to outgassing can be observed as the initial capacitance multiplied by a factor. An example plot 370 of an example multiplying factor is shown in FIG. 3C. In the illustrated example of FIG. 3C, multiplication factors are shown for a deflection range of 0 nm to 2500 nm under the assumption of CO₂ outgassing with a dielectric constant of K=1.1. As shown in the illustrated example of FIG. 3C, the variation in capacitance is exponentially decaying with deflection, which enables an ability to detect swell conditions very early in any outgassing occurrence. While alternate materials and other parameters may exhibit an alternately shaped plot as compared to the illustrated example of FIG. 3C, outgassing phenomenon can be observed prior to substantial battery damage and/or physical damage to any device in which the battery operates.

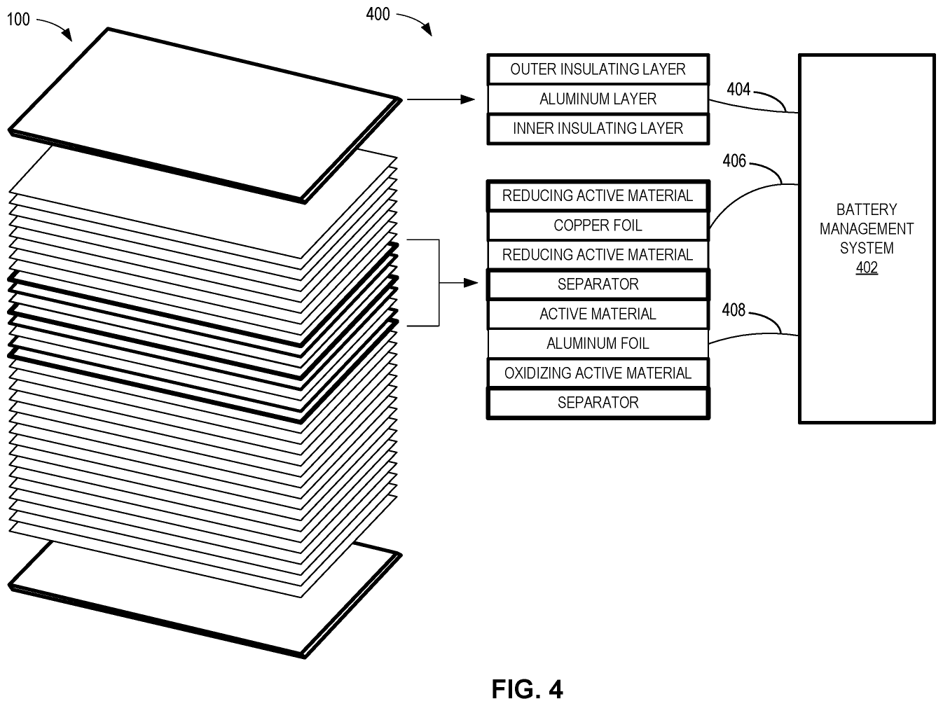

FIG. 4 is a structural diagram (block diagram) of an example pouch-type stacked cell battery environment 400 in which an example battery management system (BMS) 402 operates to manage battery outgassing conditions. The illustrated example of FIG. 4 is substantially similar to the illustrated example of FIG. 1A, and similar labels are shown. However, the example battery 100 of FIG. 4 includes the example BMS 402, and an example pouch connector 404. The example battery 100 of FIG. 4 also illustrates an example anode connector 406 and an example cathode connector 408, both of which are components typically existing in most battery configurations. In some examples, the anode connector 406, the cathode connector 408 and the pouch connector 404 include physical wires connected to the example BMS 402. The example pouch connector 404 may electrically connect to a conductive layer of the battery 100, such as the example aluminum layer 106. In particular, the conductive layer of the battery 100 is proximate to an enclosure for the battery and its corresponding layers. In some examples, the conductive layer of the battery 100 is the aluminum layer 106 and faces the interior of the battery and its corresponding layers while the opposite side of the aluminum layer 106 is adjacent to the aluminum layer and is non-conductive and/or otherwise insulating (e.g., an insulating material) and faces an outer boundary of the battery 100.

In operation, examples disclosed herein utilize one of three connector combinations to identify and/or otherwise detect a capacitance value of the example battery 100 (and/or the example battery within the example environment 400). A first example combination includes the example pouch connector 404 and the example anode connector 406. A second example combination includes the example pouch connector 404 and the example cathode connector 408. A third example combination includes the example anode connector 406 and the example cathode connector 408. In either of the first two example cases, a common connector used by examples disclosed herein to identify and/or otherwise detect a capacitance value of the battery is the pouch connector 404. In some examples, the anode connector 406 is a first distance from the aluminum layer and the cathode connector 408 is a second distance from the aluminum layer 106, the second distance greater than the first distance. However, in some battery types the cathode connector (e.g., cathode layer) may be closer to the aluminum layer 106 and the anode connector (e.g., anode layer) may be relatively farther away. In either case, the spatial distance from the aluminum layer 106 and a respective anode or cathode establishes a particular capacitance value to be detected by examples disclosed herein in an effort to manage outgassing phenomena. While the illustrated example of FIG. 4 includes a single anode connector 406 and a single cathode connector 408, examples disclosed herein are not limited thereto. In some examples, any number of anode connectors 406 or cathode connectors 408 may be used in a battery structure for the purpose of acquiring capacitance values to manage outgassing phenomena.

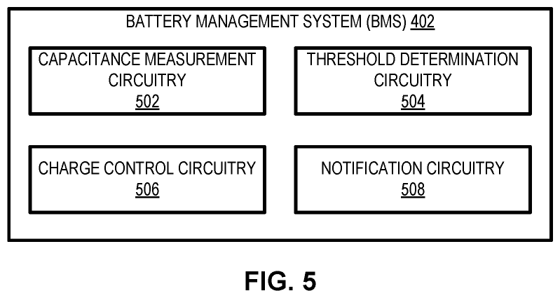

The example connector combination operates as an input to the BMS 402, which includes, in part, capacitance measurement circuitry to calculate a capacitance value of one or more portions of the battery 100. In some examples disclosed herein, the capacitance measurement circuitry is referred to as “capacitance circuitry,” or a “capacitance circuit.” FIG. 5 is a block diagram of the example BMS 402 to manage battery outgassing conditions. In the illustrated example of FIG. 5, the BMS 402 includes example capacitance measurement circuitry 502, example threshold determination circuitry 504, example charge control circuitry 506, and example notification circuitry 508. In operation, the example capacitance measurement circuitry 502 acquires a capacitance value. As described above, the capacitance value is acquired and/or otherwise calculated based on inputs from (a) the pouch connector 404 and the anode connector 406, (b) the pouch connector 404 and the cathode connector 408, or (c) the anode connector 406 and the cathode connector 408. In some examples, the capacitance circuit 502 includes and/or is otherwise coupled to memory to store capacitance information (e.g., capacitance values). The example charge control circuitry 506 determines if the battery is already being charged under an altered charge condition. Generally speaking, a normal charge condition includes a first current level corresponding to a maximum current value that the battery is designed to receive during a charge cycle. In some examples, the normal charge condition occurs for a first duration or a first duty cycle until a target state of charge (SoC) value is reached. In some examples, the current value is maintained constant until a particular voltage is detected, at which point a charging technique may change to a constant voltage where a voltage value is maintained constant until a current consumption value reduces to a particular rate to indicate a fully charged condition (or an intermediate condition where a cycle of constant current and constant voltage may be regulated). In some examples, a processor, processor circuitry, or a controller may be communicatively coupled to the example charge control circuitry 506 to invoke the charge control circuitry 506 based on input data from the example capacitance circuit 502.

As a battery ages and/or experiences a particular number of charge/discharge cycles, the ability for the battery to accept the first current value during the charging cycle reduces. In some examples, this battery degradation results in outgassing when the first current value is used during the charging cycle. However, in the event the first current value is decreased to a second and relatively lower current value, outgassing phenomena decrease for the battery and the battery lifetime may be extended. If the example charge control circuitry 506 determines that the battery is already being charged under an altered charge condition (e.g., a relatively lower current charge condition in an effort to reduce outgassing), then that particular charge condition is maintained during subsequent battery monitoring efforts. In some examples, a first augmented charge condition is referred to as a first-tier condition.

On the other hand, if the example charge control circuitry 506 determines that the battery is operating without any augmented charge conditions (e.g., a normal charge condition that applies a maximum target current to the battery), then the example threshold determination circuitry 504 determines and/or otherwise measures a capacitance value of the battery to determine whether it satisfies a first threshold value. For example, each particular battery design may exhibit a normal and/or otherwise initial capacitance value indicative of a particular capacitance or capacitance range of values expected when the battery is new and/or otherwise recently manufactured. In some examples, battery manufacturers provide particular normal capacitance values expected during normal operating conditions of the battery. In some examples, the normal capacitance values are stored in a memory of the example BMS 402 and/or within the example threshold determination circuitry 504 to be used when determining whether the battery is in need of an altered charge control mode. In some examples, a first capacitance threshold value is empirically determined and/or provided by the battery manufacturer based on a capacitance value that occurs when outgassing is likely to be occurring. In some examples, the threshold determination circuitry 504 determines, measures and/or otherwise calculates a magnitude value of a difference between a measured capacitance value and one or more threshold values of interest.

If the example threshold determination circuitry 504 determines that a current capacitance value satisfies (e.g., passes, breaches) a first threshold value, then the example charge control circuitry 506 instantiates a first-tier charge condition. Stated differently, now that the battery exhibits an indication that outgassing may be occurring (e.g., because a capacitance value of the battery is lower than a normal capacitance value, which may be caused by an increase in the separation of one or more layers of the battery due to outgassing pressure(s)), the charge control circuitry 506 can take measures to prolong the battery life and/or prevent physical damage to the device in which the battery operates. As described above, the charge control circuitry 506 is connected via a first conductive surface (e.g., a first wire, a first conductive lead) to the example anode 114 and connected via a second conductive surface (e.g., a second wire, a second conductive lead) to the example cathode 116 to provide charge current to the example battery 100, in which the charge current or altered charge termination voltage is based on an output value of the example capacitance measurement circuitry 502.

In the event the example threshold determination circuitry 504 determines that the current capacitance value satisfies (e.g., breaches, passes) a first threshold value (e.g., a capacitance value lower than a normal capacitance value), the possibility exists that the current capacitance value also satisfies a second threshold value (e.g., a capacitance value lower than the first threshold value and greater than a third threshold value). For instance, because battery degradation may continue and/or otherwise get worse over time and charge/discharge cycles, a corresponding capacitance value may reveal this degradation by getting progressively lower as one or more layers of the battery separate further apart due to outgassing. As such, examples disclosed herein facilitate altered charge modes for the example battery in a manner proportionate to the degree of battery degradation. In some examples, batteries that exhibit a capacitance value that satisfies the first threshold are at an early stage of battery degradation that can still receive a first-tier charge current lower than the normal charge current. However, in some examples batteries that exhibit a capacitance value that satisfies the second threshold are at a relatively greater stage of battery degradation that require a relatively lower charge current value or lower charge termination voltage in an effort to prolong the battery lifespan.

When the example threshold determination circuitry 504 determines that the current capacitance value satisfies a second threshold, then the example charge control circuitry 506 instantiates a second-tier charge control mode. As described above, the second-tier charge control mode causes charge circuitry of the example BMS 402 to charge the example battery 100 at a current less than (a) a charge current corresponding to the first-tier charge control mode and (b) a charge current corresponding to the normal charge control mode or lower charge termination voltage. In any circumstance where the example threshold determination circuitry 504 determines that a capacitance threshold is satisfied, the example notification circuitry 508 generates a notification signal and/or message. In some examples, the BMS 402 includes a display and/or indicator to identify a battery health condition and/or a particular tier charge control mode. In some examples, the notification signal and/or message is provided as an output for processing and/or interpretation by an external or third party alarm system. In some examples, the display identifies and/or otherwise renders information corresponding to one or more charge control modes of the battery. In some examples, one or more batteries may reside within an enclosure, for which the example display identifies and/or otherwise renders information corresponding to the enclosure (e.g., a control mode of the enclosure, a voltage of the enclosure, battery health information, etc.).

As described above, FIG. 5 is a block diagram of an example implementation of the example battery management system of FIG. 4 to do battery outgassing management. The battery management system of FIG. 5 may be instantiated (e.g., creating an instance of, bring into being for any length of time, materialize, implement, etc.) by programmable circuitry such as a Central Processor Unit (CPU) executing first instructions. Additionally or alternatively, the battery management system of FIG. 5 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 4 may, thus, be instantiated at the same or different times. Some or all of the circuitry of FIG. 5 may be instantiated, for example, in one or more threads executing concurrently on hardware and/or in series on hardware (e.g., local hardware, cloud-based hardware distributed on one or more networks, etc.). Moreover, in some examples, some or all of the circuitry of FIG. 5 may be implemented by microprocessor circuitry executing instructions and/or FPGA circuitry performing operations to implement one or more virtual machines and/or containers.

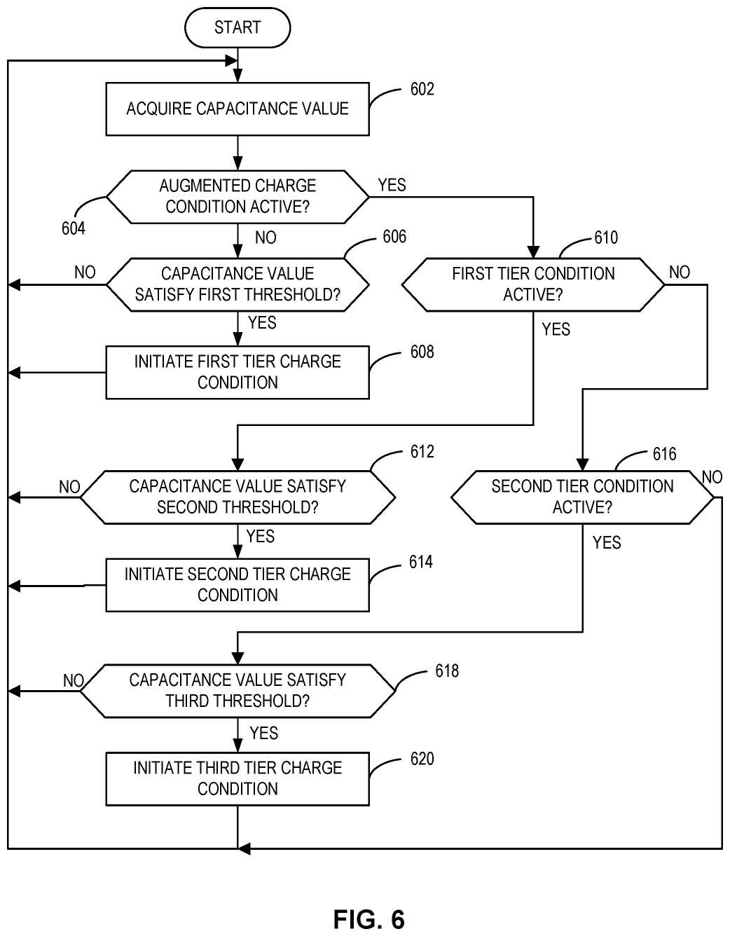

In some examples, the capacitance measurement circuitry 502 is instantiated by programmable circuitry executing capacitance measurement instructions and/or configured to perform operations such as those represented by the flowchart(s) of FIG. 6. In some examples, the threshold determination circuitry 504 is instantiated by programmable circuitry executing threshold determination instructions and/or configured to perform operations such as those represented by the flowchart(s) of FIG. 6. In some examples, the charge control circuitry 506 is instantiated by programmable circuitry executing charge control instructions and/or configured to perform operations such as those represented by the flowchart(s) of FIG. 6. In some examples, the notification circuitry 508 is instantiated by programmable circuitry executing notification instructions and/or configured to perform operations such as those represented by the flowchart(s) of FIG. 6.

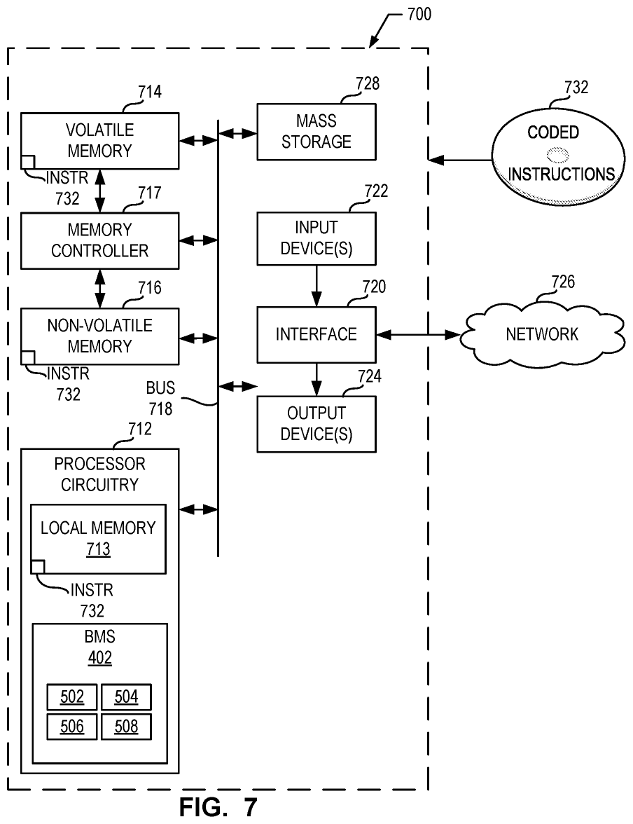

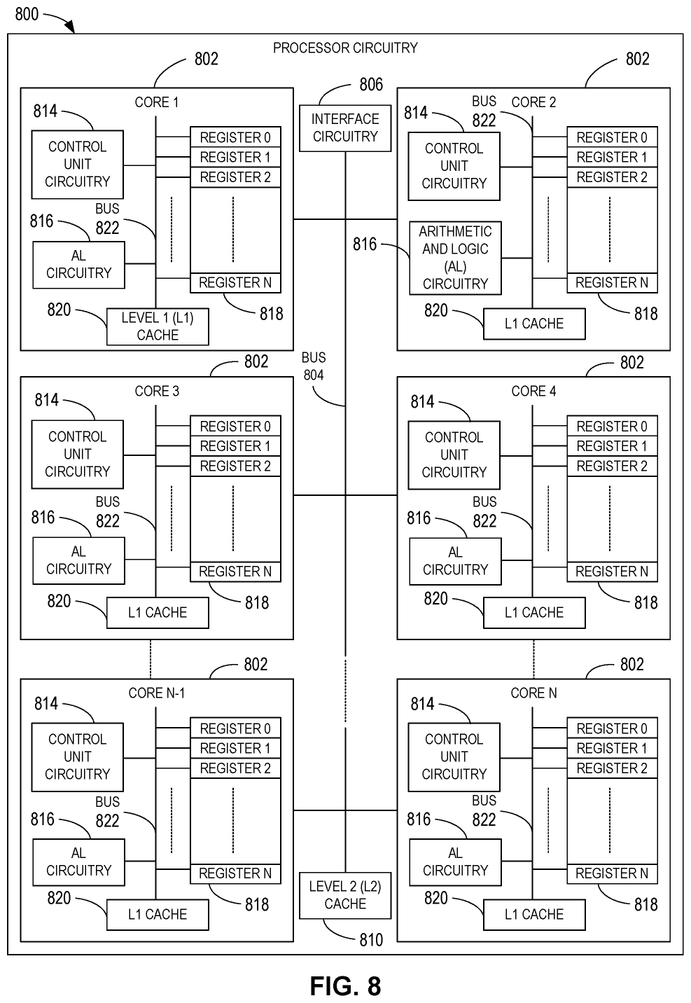

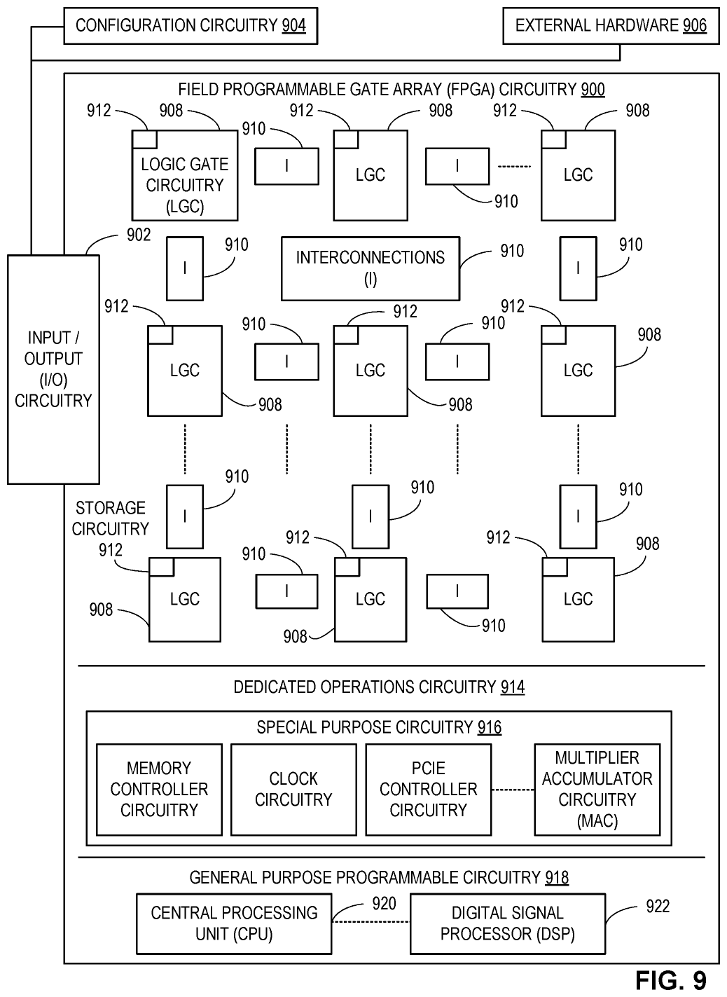

In some examples, the BMS 402 includes means for capacitance measurement. For example, the means for capacitance measurement may be implemented by the capacitance measurement circuitry 502. In some examples, the capacitance measurement circuitry 502 may be instantiated by programmable circuitry such as the example programmable circuitry 712 of FIG. 7. For instance, the capacitance measurement circuitry 502 may be instantiated by the example microprocessor 800 of FIG. 8 executing machine executable instructions such as those implemented by one or more blocks of FIG. 6. In some examples, capacitance measurement circuitry 502 may be instantiated by hardware logic circuitry, which may be implemented by an ASIC, XPU, or the FPGA circuitry 900 of FIG. 9 configured and/or structured to perform operations corresponding to the machine readable instructions. Additionally or alternatively, the capacitance measurement circuitry 502 may be instantiated by any other combination of hardware, software, and/or firmware. For example, the capacitance measurement circuitry 502 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the battery management system 402 includes means for threshold determination. For example, the means for threshold determination may be implemented by threshold determination circuitry 504. In some examples, the threshold determination circuitry 504 may be instantiated by programmable circuitry such as the example programmable circuitry 712 of FIG. 7. For instance, the threshold determination circuitry 504 may be instantiated by the example microprocessor 800 of FIG. 8 executing machine executable instructions such as those implemented by one or more blocks of FIG. 6. In some examples, the threshold determination circuitry 504 may be instantiated by hardware logic circuitry, which may be implemented by an ASIC, XPU, or the FPGA circuitry 900 of FIG. 9 configured and/or structured to perform operations corresponding to the machine readable instructions. Additionally or alternatively, the threshold determination circuitry 504 may be instantiated by any other combination of hardware, software, and/or firmware. For example, the threshold determination circuitry 504 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the battery management system 402 includes means for charge control. For example, the means for charge control may be implemented by charge control circuitry 506. In some examples, the charge control circuitry 506 may be instantiated by programmable circuitry such as the example programmable circuitry 712 of FIG. 7. For instance, the charge control circuitry 506 may be instantiated by the example microprocessor 800 of FIG. 8 executing machine executable instructions such as those implemented by one or more blocks of FIG. 6. In some examples, charge control circuitry 506 may be instantiated by hardware logic circuitry, which may be implemented by an ASIC, XPU, or the FPGA circuitry 900 of FIG. 9 configured and/or structured to perform operations corresponding to the machine readable instructions. Additionally or alternatively, the charge control circuitry 506 may be instantiated by any other combination of hardware, software, and/or firmware. For example, the charge control circuitry 506 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the battery management system 402 includes means for notification. For example, the means for notification may be implemented by notification circuitry 508. In some examples, the notification circuitry 508 may be instantiated by programmable circuitry such as the example programmable circuitry 712 of FIG. 7. For instance, the notification circuitry 508 may be instantiated by the example microprocessor 800 of FIG. 8 executing machine executable instructions such as those implemented by one or more blocks of FIG. 6. In some examples, the notification circuitry 508 may be instantiated by hardware logic circuitry, which may be implemented by an ASIC, XPU, or the FPGA circuitry 900 of FIG. 9 configured and/or structured to perform operations corresponding to the machine readable instructions. Additionally or alternatively, the notification circuitry 508 may be instantiated by any other combination of hardware, software, and/or firmware. For example, the notification circuitry 508 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the battery management system 402 of FIG. 4 is illustrated in FIG. 5, one or more of the elements, processes, and/or devices illustrated in FIG. 5 may be combined, divided, re-arranged, omitted, eliminated, and/or implemented in any other way. Further, the example capacitance measurement circuitry 502, the example threshold determination circuitry 504, the example charge control circuitry 506, the example notification circuitry 508, and/or, more generally, the example battery management system 402 of FIG. 5, may be implemented by hardware alone or by hardware in combination with software and/or firmware. Thus, for example, any of the capacitance measurement circuitry 502, the example threshold determination circuitry 504, the example charge control circuitry 506, the example notification circuitry 508, and/or, more generally, the example battery management system 402, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example battery management system 402 of FIG. 5 may include one or more elements, processes, and/or devices in addition to, or instead of, those illustrated in FIG. 5, and/or may include more than one of any or all of the illustrated elements, processes and devices.

Flowchart(s) representative of example machine readable instructions, which may be executed by programmable circuitry to implement and/or instantiate the battery management system 402 of FIG. 5 and/or representative of example operations which may be performed by programmable circuitry to implement and/or instantiate the battery management system 402 of FIG. 5, are shown in FIG. 6. The machine readable instructions may be one or more executable programs or portion(s) of one or more executable programs for execution by programmable circuitry such as the programmable circuitry 712 shown in the example processor platform 700 discussed below in connection with FIG. 7 and/or may be one or more function(s) or portion(s) of functions to be performed by the example programmable circuitry (e.g., an FPGA) discussed below in connection with FIGS. 8 and/or 9. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 6, many other methods of implementing the example battery management system 402 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 6 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C.

As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 6 is a flowchart representative of example machine readable instructions and/or example operations 600 that may be executed, instantiated, and/or performed by programmable circuitry to manage outgassing conditions of a battery. The example machine-readable instructions and/or the example operations 600 of FIG. 6 begin at block 602, at which the example capacitance measurement circuitry 502 acquires a capacitance value from a battery (e.g., the example battery 100 of FIG. 4). As described above, the example BMS 402 is coupled to a first conductive surface that is proximate to an outer surface of the battery 100, and that first conductive surface is also connected to the example capacitance measurement circuitry 502. In some examples, the first conductive surface is a wire (e.g., a conductive lead) connected to the aluminum layer 106 of the battery, in which the aluminum layer 106 is directly underneath (proximate) to an outer insulating pouch layer 102. In some examples, the wire is coupled to the aluminum layer 106 by first etching and/or otherwise removing a small portion of insulation material of the outer surface of the battery 100. The example capacitance measurement circuitry 502 is also coupled to at least a second conductive surface of that battery. In particular, the capacitance measurement circuitry 502 is coupled to either the anode 114 or the cathode 116 of the battery 100. As such, the example capacitance measurement circuitry 502 acquires and/or otherwise measures a capacitance value (block 602) of the battery 100 based on analysis of the inputs from one of (a) the aluminum layer 106 and the anode 114 or (b) the aluminum layer 106 and the cathode 116.

The example charge control circuitry 506 determines if an augmented charge mode is currently active (block 604). If not, then the example threshold determination circuitry 504 determines whether the measured capacitance value satisfies a first threshold (block 606). If not, then control returns to block 602 and the example capacitance measurement circuitry 502 continues to iteratively measure a capacitance value of the battery 100. On the other hand, if the threshold determination circuitry 504 determines that the measured capacitance value satisfies the first threshold (block 606), then the example charge control circuitry 506 instantiates a first-tier charge control mode for the battery 100. As described above, in response to detecting that the first threshold capacitance value is satisfied (e.g., lower than the normal capacitance value of the battery 100), examples disclosed herein determine that battery degradation has occurred to a certain degree. As such, examples disclosed herein improve battery longevity, reduce battery damage and/or reduce device damage by instantiating the first-tier charge control mode (block 608) so that charge input currents are lower than they otherwise would be absent such monitoring efforts. In some examples, the charge control circuitry 506 maintains a flag and/or any other data structure type to keep track of a current battery control mode. In some examples, a charge control data structure is set as a particular numeric value to identify which charge control mode is active (e.g., value 0 indicates no control mode is active, value 1 indicates a first-tier charge control mode is active, value 2 indicates a second-tier charge control mode is active, etc.). Control then returns block 602 and the example capacitance measurement circuitry 502 continues to iteratively measure a capacitance value of the battery 100.

Briefly returning to block 604, the example charge control circuitry 506 determines whether the battery is already in any particular charge control mode (e.g., a first-tier charge control mode, a second-tier charge control mode, etc.). If this is true (block 604=YES), then the example charge control circuitry 506 determines which particular type of charge control mode is active, but does not turn off and/or otherwise disturb an existing charge control mode that is currently attempting to prolong the battery life. In particular, the example charge control circuitry 506 determines whether the batter is currently set as a first-tier condition (block 610). As described above, the example charge control circuitry 506 may read a value of a charge control data structure for a value indicative of the type of charge control that is active. For the sake of this example, when the charge control circuitry 506 detects an indication that the first-tier charge control is active (e.g., the data structure contains a value of 1), then the example threshold determination circuitry 504 determines if the capacitance value satisfies a second threshold (block 612). If not (block 612=NO), then control returns to block 602 to continue iterative monitoring because the battery condition has not changed enough to justify a change to the charge control scheme. On the other hand, if the threshold determination circuitry 504 determines that the capacitance value satisfies the second threshold (block 612=YES), then the charge control circuitry 506 instantiates a second-tier charge mode (block 614) and control returns to block 602.

Briefly returning to block 610, if the example charge control circuitry 506 determines that the first-tier condition/mode is not active (e.g., the charge control data structure does not equal 1), then the charge control circuitry 506 determines if the second-tier mode is active (block 616). If so, then the threshold determination circuitry 504 determines whether the capacitance value satisfies a third threshold value (block 618). In some examples, the third threshold value is indicative of a most severe case of battery swelling for which the most drastic charge control mode is required. In some examples, the third threshold value is indicative of circumstances where the battery should not operate further due to potential safety concerns. In the event the threshold determination circuitry 504 determines that the third threshold is not active (block 618=NO), then the capacitance value of the battery is still operating within the boundaries of the second threshold and no changes to the charge control mode are applied. Control then returns to block 602 to allow the environment 400 to continue monitoring the battery 100. However, if the threshold determination circuitry 504 determines that the third threshold is active (block 618=YES), then the example charge control circuitry 506 instantiates a third-tier charge condition for the battery 100 (block 620), and control returns to block 602 to allow the environment 400 to continue monitoring the battery 100. However, in some examples the charge control circuitry 506 prohibits any further charging attempts in response to instantiating the third tier-charge condition. In particular, in the event the third-tier charge condition is associated with a safety concern, then further battery charging attempts are prohibited to avoid dangerous results such as fires, explosions and/or swell conditions that may permanently damage a device in which the battery operates. In some examples, a range of capacitance thresholds determine whether the battery is permitted to charge (e.g., a permissive charge condition) or whether the battery is prohibited from further charging (e.g., a prohibit charge condition).

FIG. 7 is a block diagram of an example programmable circuitry platform 700 structured to execute and/or instantiate the example machine-readable instructions and/or the example operations of FIG. 6 to implement the battery management system 402 of FIG. 5. The programmable circuitry platform 700 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 700 of the illustrated example includes programmable circuitry 712. The programmable circuitry 712 of the illustrated example is hardware. For example, the programmable circuitry 712 can be implemented by one or more integrated circuits, logic circuits, FPGAs, microprocessors, CPUs, GPUs, DSPs, and/or microcontrollers from any desired family or manufacturer. The programmable circuitry 712 may be implemented by one or more semiconductor based (e.g., silicon based) devices. In this example, the programmable circuitry 712 implements the example capacitance measurement circuitry 502, the example threshold determination circuitry 504, the example charge control circuitry 506, the example notification circuitry 508, and more generally the example BMS 402.

The programmable circuitry 712 of the illustrated example includes a local memory 713 (e.g., a cache, registers, etc.). The programmable circuitry 712 of the illustrated example is in communication with main memory 714, 716, which includes a volatile memory 714 and a non-volatile memory 716, by a bus 718. The volatile memory 714 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 716 may be implemented by flash memory and/or any other desired type of memory device. Access to the main memory 714, 716 of the illustrated example is controlled by a memory controller 717. In some examples, the memory controller 717 may be implemented by one or more integrated circuits, logic circuits, microcontrollers from any desired family or manufacturer, or any other type of circuitry to manage the flow of data going to and from the main memory 714, 716.

The programmable circuitry platform 700 of the illustrated example also includes interface circuitry 720. The interface circuitry 720 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 722 are connected to the interface circuitry 720. The input device(s) 722 permit(s) a user (e.g., a human user, a machine user, etc.) to enter data and/or commands into the programmable circuitry 712. The input device(s) 722 can be implemented by, for example, a button, a mouse, a touchscreen, a trackpad, a trackball, an isopoint device, and/or a voice recognition system.

One or more output devices 724 are also connected to the interface circuitry 720 of the illustrated example. The output device(s) 724 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 720 of the illustrated example, thus, typically includes a graphics driver card, a graphics driver chip, and/or graphics processor circuitry such as a GPU.

The interface circuitry 720 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 726. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 700 of the illustrated example also includes one or more mass storage discs or devices 728 to store firmware, software, and/or data. Examples of such mass storage discs or devices 728 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 732, which may be implemented by the machine readable instructions of FIG. 6, may be stored in the mass storage device 728, in the volatile memory 714, in the non-volatile memory 716, and/or on at least one non-transitory computer readable storage medium such as a CD or DVD which may be removable.

FIG. 8 is a block diagram of an example implementation of the programmable circuitry 712 of FIG. 7. In this example, the programmable circuitry 712 of FIG. 7 is implemented by a microprocessor 800. For example, the microprocessor 800 may be a general-purpose microprocessor (e.g., general-purpose microprocessor circuitry). The microprocessor 800 executes some or all of the machine-readable instructions of the flowcharts of FIG. 6 to effectively instantiate the circuitry of FIG. 2 as logic circuits to perform operations corresponding to those machine readable instructions. In some such examples, the circuitry of FIG. 5 is instantiated by the hardware circuits of the microprocessor 800 in combination with the machine-readable instructions. For example, the microprocessor 800 may be implemented by multi-core hardware circuitry such as a CPU, a DSP, a GPU, an XPU, etc. 45-lthoughh it may include any number of example cores 802 (e.g., 1 core), the microprocessor 800 of this example is a multi-core semiconductor device including N cores. The cores 802 of the microprocessor 800 may operate independently or may cooperate to execute machine readable instructions. For example, machine code corresponding to a firmware program, an embedded software program, or a software program may be executed by one of the cores 802 or may be executed by multiple ones of the cores 802 at the same or different times. In some examples, the machine code corresponding to the firmware program, the embedded software program, or the software program is split into threads and executed in parallel by two or more of the cores 802. The software program may correspond to a portion or all of the machine readable instructions and/or operations represented by the flowcharts of FIG. 6.

The cores 802 may communicate by a first example bus 804. In some examples, the first bus 804 may be implemented by a communication bus to effectuate communication associated with one(s) of the cores 802. For example, the first bus 804 may be implemented by at least one of an Inter-Integrated Circuit (I2C) bus, a Serial Peripheral Interface (SPI) bus, a PCI bus, or a PCIe bus. Additionally or alternatively, the first bus 804 may be implemented by any other type of computing or electrical bus. The cores 802 may obtain data, instructions, and/or signals from one or more external devices by example interface circuitry 806. The cores 802 may output data, instructions, and/or signals to the one or more external devices by the interface circuitry 806. Although the cores 802 of this example include example local memory 820 (e.g., Level 1 (L1) cache that may be split into an L1 data cache and an L1 instruction cache), the microprocessor 800 also includes example shared memory 810 that may be shared by the cores (e.g., Level 2 (L2 cache)) for high-speed access to data and/or instructions. Data and/or instructions may be transferred (e.g., shared) by writing to and/or reading from the shared memory 810. The local memory 820 of each of the cores 802 and the shared memory 810 may be part of a hierarchy of storage devices including multiple levels of cache memory and the main memory (e.g., the main memory 714, 716 of FIG. 7). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 802 may be referred to as a CPU, DSP, GPU, etc., or any other type of hardware circuitry. Each core 802 includes control unit circuitry 814, arithmetic and logic (AL) circuitry (sometimes referred to as an ALU) 816, a plurality of registers 818, the local memory 820, and a second example bus 822. Other structures may be present. For example, each core 802 may include vector unit circuitry, single instruction multiple data (SIMD) unit circuitry, load/store unit (LSU) circuitry, branch/jump unit circuitry, floating-point unit (FPU) circuitry, etc. The control unit circuitry 814 includes semiconductor-based circuits structured to control (e.g., coordinate) data movement within the corresponding core 802. The AL circuitry 816 includes semiconductor-based circuits structured to perform one or more mathematic and/or logic operations on the data within the corresponding core 802. The AL circuitry 816 of some examples performs integer based operations. In other examples, the AL circuitry 816 also performs floating-point operations. In yet other examples, the AL circuitry 816 may include first AL circuitry that performs integer-based operations and second AL circuitry that performs floating-point operations. In some examples, the AL circuitry 816 may be referred to as an Arithmetic Logic Unit (ALU).

The registers 818 are semiconductor-based structures to store data and/or instructions such as results of one or more of the operations performed by the AL circuitry 816 of the corresponding core 802. For example, the registers 818 may include vector register(s), SIMD register(s), general-purpose register(s), flag register(s), segment register(s), machine-specific register(s), instruction pointer register(s), control register(s), debug register(s), memory management register(s), machine check register(s), etc. The registers 818 may be arranged in a bank as shown in FIG. 8. Alternatively, the registers 818 may be organized in any other arrangement, format, or structure, such as by being distributed throughout the core 802 to shorten access time. The second bus 822 may be implemented by at least one of an I2C bus, a SPI bus, a PCI bus, or a PCIe bus.

Each core 802 and/or, more generally, the microprocessor 800 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 800 is a semiconductor device fabricated to include many transistors interconnected to implement the structures described above in one or more integrated circuits (Ics) contained in one or more packages.

The microprocessor 800 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 800, in the same chip package as the microprocessor 800 and/or in one or more separate packages from the microprocessor 800.

FIG. 9 is a block diagram of another example implementation of the programmable circuitry 712 of FIG. 7. In this example, the programmable circuitry 712 is implemented by FPGA circuitry 900. For example, the FPGA circuitry 900 may be implemented by an FPGA. The FPGA circuitry 900 can be used, for example, to perform operations that could otherwise be performed by the example microprocessor 800 of FIG. 8 executing corresponding machine readable instructions. However, once configured, the FPGA circuitry 900 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 800 of FIG. 8 described above (which is a general purpose device that may be programmed to execute some or all of the machine readable instructions represented by the flowchart(s) of FIG. 6 but whose interconnections and logic circuitry are fixed once fabricated), the FPGA circuitry 900 of the example of FIG. 9 includes interconnections and logic circuitry that may be configured, structured, programmed, and/or interconnected in different ways after fabrication to instantiate, for example, some or all of the operations/functions corresponding to the machine readable instructions represented by the flowchart(s) of FIG. 6. In particular, the FPGA circuitry 900 may be thought of as an array of logic gates, interconnections, and switches. The switches can be programmed to change how the logic gates are interconnected by the interconnections, effectively forming one or more dedicated logic circuits (unless and until the FPGA circuitry 900 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIG. 6. As such, the FPGA circuitry 900 may be configured and/or structured to effectively instantiate some or all of the operations/functions corresponding to the machine readable instructions of the flowchart(s) of FIG. 6 as dedicated logic circuits to perform the operations/functions corresponding to those software instructions in a dedicated manner analogous to an ASIC. Therefore, the FPGA circuitry 900 may perform the operations/functions corresponding to the some or all of the machine readable instructions of FIG. 6 faster than the general-purpose microprocessor can execute the same.

In the example of FIG. 9, the FPGA circuitry 900 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 900 of FIG. 9 may access and/or load the binary file to cause the FPGA circuitry 900 of FIG. 9 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 900 of FIG. 9 to cause configuration and/or structuring of the FPGA circuitry 900 of FIG. 9, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 900 of FIG. 9 may access and/or load the binary file to cause the FPGA circuitry 900 of FIG. 9 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 900 of FIG. 9 to cause configuration and/or structuring of the FPGA circuitry 900 of FIG. 9, or portion(s) thereof.

The FPGA circuitry 900 of FIG. 9, includes example input/output (I/O) circuitry 902 to obtain and/or output data to/from example configuration circuitry 904 and/or external hardware 906. For example, the configuration circuitry 904 may be implemented by interface circuitry that may obtain a binary file, which may be implemented by a bit stream, data, and/or machine-readable instructions, to configure the FPGA circuitry 900, or portion(s) thereof. In some such examples, the configuration circuitry 904 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 906 may be implemented by external hardware circuitry. For example, the external hardware 906 may be implemented by the microprocessor 800 of FIG. 8.

The FPGA circuitry 900 also includes an array of example logic gate circuitry 908, a plurality of example configurable interconnections 910, and example storage circuitry 912. The logic gate circuitry 908 and the configurable interconnections 910 are configurable to instantiate one or more operations/functions that may correspond to at least some of the machine readable instructions of FIG. 6 and/or other desired operations. The logic gate circuitry 908 shown in FIG. 9 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 908 to enable configuration of the electrical structures and/or the logic gates to form circuits to perform desired operations/functions. The logic gate circuitry 908 may include other electrical structures such as look-up tables (LUTs), registers (e.g., flip-flops or latches), multiplexers, etc.

The configurable interconnections 910 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 908 to program desired logic circuits.

The storage circuitry 912 of the illustrated example is structured to store result(s) of the one or more of the operations performed by corresponding logic gates. The storage circuitry 912 may be implemented by registers or the like. In the illustrated example, the storage circuitry 912 is distributed amongst the logic gate circuitry 908 to facilitate access and increase execution speed.

The example FPGA circuitry 900 of FIG. 9 also includes example dedicated operations circuitry 914. In this example, the dedicated operations circuitry 914 includes special purpose circuitry 916 that may be invoked to implement commonly used functions to avoid the need to program those functions in the field. Examples of such special purpose circuitry 916 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 900 may also include example general purpose programmable circuitry 918 such as an example CPU 920 and/or an example DSP 922. Other general purpose programmable circuitry 918 may additionally or alternatively be present such as a GPU, an XPU, etc., that can be programmed to perform other operations.

Although FIGS. 8 and 9 illustrate two example implementations of the programmable circuitry 712 of FIG. 7, many other approaches are contemplated. For example, FPGA circuitry may include an on-board CPU, such as one or more of the example CPU 920 of FIG. 8. Therefore, the programmable circuitry 712 of FIG. 7 may additionally be implemented by combining at least the example microprocessor 800 of FIG. 8 and the example FPGA circuitry 900 of FIG. 9. In some such hybrid examples, one or more cores 802 of FIG. 8 may execute a first portion of the machine readable instructions represented by the flowchart(s) of FIG. 6 to perform first operation(s)/function(s), the FPGA circuitry 900 of FIG. 9 may be configured and/or structured to perform second operation(s)/function(s) corresponding to a second portion of the machine readable instructions represented by the flowcharts of FIG. 6, and/or an ASIC may be configured and/or structured to perform third operation(s)/function(s) corresponding to a third portion of the machine readable instructions represented by the flowcharts of FIG. 6.

It should be understood that some or all of the circuitry of FIG. 5 may, thus, be instantiated at the same or different times. For example, same and/or different portion(s) of the microprocessor 800 of FIG. 8 may be programmed to execute portion(s) of machine-readable instructions at the same and/or different times. In some examples, same and/or different portion(s) of the FPGA circuitry 900 of FIG. 9 may be configured and/or structured to perform operations/functions corresponding to portion(s) of machine-readable instructions at the same and/or different times.

In some examples, some or all of the circuitry of FIG. 5 may be instantiated, for example, in one or more threads executing concurrently and/or in series. For example, the microprocessor 800 of FIG. 8 may execute machine readable instructions in one or more threads executing concurrently and/or in series. In some examples, the FPGA circuitry 900 of FIG. 9 may be configured and/or structured to carry out operations/functions concurrently and/or in series. Moreover, in some examples, some or all of the circuitry of FIG. 5 may be implemented within one or more virtual machines and/or containers executing on the microprocessor 800 of FIG. 8.

In some examples, the programmable circuitry 712 of FIG. 7 may be in one or more packages. For example, the microprocessor 800 of FIG. 8 and/or the FPGA circuitry 900 of FIG. 9 may be in one or more packages. In some examples, an XPU may be implemented by the programmable circuitry 712 of FIG. 7, which may be in one or more packages. For example, the XPU may include a CPU (e.g., the microprocessor 800 of FIG. 8, the CPU 920 of FIG. 9, etc.) in one package, a DSP (e.g., the DSP 922 of FIG. 9) in another package, a GPU in yet another package, and an FPGA (e.g., the FPGA circuitry 900 of FIG. 9) in still yet another package.

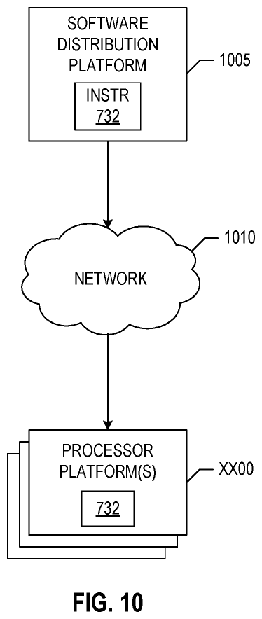

A block diagram illustrating an example software distribution platform 1005 to distribute software such as the example machine readable instructions 732 of FIG. 7 to other hardware devices (e.g., hardware devices owned and/or operated by third parties from the owner and/or operator of the software distribution platform) is illustrated in FIG. 10. The example software distribution platform 1005 may be implemented by any computer server, data facility, cloud service, etc., capable of storing and transmitting software to other computing devices. The third parties may be customers of the entity owning and/or operating the software distribution platform 1005. For example, the entity that owns and/or operates the software distribution platform 1005 may be a developer, a seller, and/or a licensor of software such as the example machine readable instructions 732 of FIG. 7. The third parties may be consumers, users, retailers, OEMs, etc., who purchase and/or license the software for use and/or re-sale and/or sub-licensing. In the illustrated example, the software distribution platform 1005 includes one or more servers and one or more storage devices. The storage devices store the machine readable instructions 732, which may correspond to the example machine readable instructions of FIG. 6, as described above. The one or more servers of the example software distribution platform 1005 are in communication with an example network 1010, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 732 from the software distribution platform 1005. For example, the software, which may correspond to the example machine readable instructions of FIG. 6, may be downloaded to the example programmable circuitry platform 700, which is to execute the machine readable instructions 732 to implement the battery management system 402. In some examples, one or more servers of the software distribution platform 1005 periodically offer, transmit, and/or force updates to the software (e.g., the example machine readable instructions 732 of FIG. 7) to ensure improvements, patches, updates, etc., are distributed and applied to the software at the end user devices. Although referred to as software above, the distributed “software” could alternatively be firmware.

Example methods, apparatus, systems, and articles of manufacture to manage battery outgassing conditions are disclosed herein. Further examples and combinations thereof include the following:

Example 1 includes an apparatus to detect battery outgassing, comprising an enclosure having a first conductive surface located proximate to an outer boundary of the enclosure, a second conductive surface located a first distance from the first conductive surface, a capacitance circuit coupled to the first conductive surface and the second conductive surface, and a charge control circuit to control an input signal to the second conductive surface and a third conductive surface based on an output of the capacitance circuit.

Example 2 includes the apparatus as defined in example 1, further including a first wire coupled to the first conductive surface and a second wire coupled to the second conductive surface.

Example 3 includes the apparatus as defined in example 2, wherein the capacitance circuit is coupled to the first conductive surface via the first wire and the capacitance circuit is coupled to the second conductive surface via the second wire.

Example 4 includes the apparatus as defined in example 1, wherein the enclosure is a battery housing.

Example 5 includes the apparatus as defined in example 4, wherein an outer layer of the enclosure is an insulating material and the first conductive surface is an aluminum material adjacent to the insulating material.

Example 6 includes the apparatus as defined in example 4, wherein the second conductive surface is at least one of an anode or a cathode of the battery housing.

Example 7 includes the apparatus as defined in example 4, wherein the battery includes two or more active layers, respective ones of the active layers including an anode having a copper foil layer between a first graphite layer and a second graphite layer, and a cathode separated from the anode with a separator, the cathode having an aluminum foil layer between a first active material and a second active material.

Example 8 includes the apparatus as defined in example 4, wherein the battery includes stacked anode layers and cathode layers.

Example 9 includes the apparatus as defined in example 4, wherein the battery includes rolled anode layers and cathode layers.

Example 10 includes the apparatus as defined in example 1, wherein the second conductive surface is one of a battery anode or a battery cathode.

Example 11 includes the apparatus as defined in example 10, wherein the third conductive surface is an other one of the battery anode or the battery cathode.

Example 12 includes the apparatus as defined in example 1, wherein the capacitance circuit is to measure a capacitance value between the first conductive surface and the second conductive surface.

Example 13 includes the apparatus as defined in example 12, further including threshold determination circuitry to determine if the capacitance value satisfies a first threshold value.

Example 14 includes the apparatus as defined in example 13, wherein the charge control circuitry is to instantiate a first-tier charge mode when the capacitance value satisfies the first threshold value.

Example 15 includes the apparatus as defined in example 12, further including threshold determination circuitry to determine if the capacitance value satisfies a failure threshold value.

Example 16 includes the apparatus as defined in example 15, wherein the charge control circuit is to prohibit charging activity when the capacitance value satisfies the failure threshold value.

Example 17 includes the apparatus as defined in example 1, further including a display to identify a charge control mode of the enclosure.

Example 18 includes the apparatus as defined in example 1, further including an electronic device to support the enclosure.

Example 19 includes the apparatus as defined in example 18, wherein the electronic device is a wireless telephone.

Example 20 includes the apparatus as defined in example 18, wherein the electronic device includes a display to render performance information corresponding to the enclosure.

Example 21 includes the apparatus as defined in example 1, further including mounting hardware to secure the enclosure to an electronic device.

Example 22 includes the apparatus as defined in example 1, further including memory to store information generated by the capacitance circuit.

Example 23 includes the apparatus as defined in example 1, further including processor circuitry to invoke the charge control circuit based on input data from the capacitance circuit.

Example 24 includes the apparatus as defined in any one of examples 1 through 6, wherein the second conductive surface is one of a battery anode or a battery cathode.

Example 25 includes the apparatus as defined in any one of examples 1 through 6, wherein the capacitance circuit is to measure a capacitance value between the first conductive surface and the second conductive surface.

Example 26 includes an apparatus to detect battery failure, comprising a housing including an insulating outer surface and a first conductive inner surface, the housing surrounding the battery, a second conductive surface located a first distance from the enclosure, means for capacitance measurement coupled to the first conductive surface and the second conductive surface, and means for charge control to adjust an input charge value to the second conductive surface and a third conductive surface based on an output value of the means for capacitance measurement.

Example 27 includes the apparatus as defined in example 26, further including a first conductive lead coupled to the first conductive inner surface and a second conductive lead coupled to the second conductive surface.

Example 28 includes the apparatus as defined in example 27, wherein the means for capacitance measurement is coupled to the first conductive inner surface with the first conductive lead, and coupled to the second conductive surface with the second conductive lead.

Example 29 includes the apparatus as defined in example 27, wherein the first conductive lead and the second conductive lead are wires.

Example 30 includes the apparatus as defined in example 26, wherein the means for capacitance measurement is to measure a capacitance value between the first conductive inner surface and the second conductive surface.

Example 31 includes the apparatus as defined in example 30, wherein the second conductive surface is at least one of an anode or a cathode of the battery.

Example 32 includes the apparatus as defined in example 26, wherein the means for capacitance measurement is to measure a capacitance value between the second conductive surface and the third conductive surface.

Example 33 includes the apparatus as defined in example 32, wherein the second conductive surface is an anode and the third conductive surface is a cathode.

Example 34 includes the apparatus as defined in example 26, further including means for threshold determination to determine if a capacitance value drops below a first threshold value.

Example 35 includes the apparatus as defined in example 34, wherein the means for charge control is to cause a first-tier charge mode when the capacitance value drops below the first threshold value.

Example 36 includes the apparatus as defined in example 26, further including means for threshold determination to determine if a capacitance value drops below a failure threshold value.

Example 37 includes the apparatus as defined in example 36, wherein the means for charge control is to block charging activity when the capacitance value drops below the failure threshold value.

Example 38 includes a method to detect outgassing of a battery, comprising measuring a capacitance value between a first conductive battery surface and a second conductive battery surface, comparing the capacitance value to a capacitance threshold value, and controlling a charge input signal to the battery based on a magnitude difference between the capacitance value and the capacitance threshold value.

Example 39 includes the method as defined in example 38, wherein the first conductive battery surface is a conductive housing of the battery and the second conductive battery surface is at least one of an anode of the battery or a cathode of the battery.

Example 40 includes the method as defined in example 38, further including determining whether the capacitance threshold value satisfies a permissive charge condition or a prohibit charge condition.

Example 41 includes the method as defined in example 40, further including preventing charging of the battery based on the prohibit charge condition.

Example 42 includes the method as defined in example 38, further including instantiating a first-tier charge mode when the capacitance value satisfies the capacitance threshold value.

Example 43 includes the method as defined in example 38, further including displaying a charge control mode of the battery.

Example 44 includes an apparatus comprising means to perform a method as set forth in any of examples 38 through example 43.

Example 45 includes machine-readable storage including machine-readable instructions to cause programmable processing circuitry to implement a method as set forth in any of examples 38 through 43.

Example 46 includes a computer program including instructions that, when the program is executed by a computer, cause the computer to carry out the method as set forth in any of examples 38 through example 43.

From the foregoing, it will be appreciated that example systems, apparatus, articles of manufacture, and methods have been disclosed that extend an operating life of batteries and/or devices in which the batteries operate. In some examples, battery capacitance monitoring examples disclosed herein enable early detection of battery degradation that, if managed shortly after degradation onset, extends a lifecycle of the battery. In some examples, particular capacitance magnitude values permit alternate charge modes to be applied to the battery so that excess charge current input values do not further cause accelerated degradation of the battery. Disclosed systems, apparatus, articles of manufacture, and methods improve the efficiency of using a battery device by prohibiting excessive charge current inputs to a battery that is experiencing swell and outgassing phenomena. As such, regulation of input charge currents facilitates a more efficient charge cycle for a battery, thereby extending its operating life and/or charge/recharge cycle count. Disclosed systems, apparatus, articles of manufacture, and methods are accordingly directed to one or more improvement(s) in the operation of a machine such as a computer or other electronic and/or mechanical device.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus to detect battery outgassing, comprising:
an enclosure having a first conductive surface located proximate to an outer boundary of the enclosure;
a second conductive surface located a first distance from the first conductive surface;
a capacitance circuit coupled to the first conductive surface and the second conductive surface; and
a charge control circuit to control an input signal to the second conductive surface and a third conductive surface based on an output of the capacitance circuit.

2. The apparatus as defined in claim 1, further including a first wire coupled to the first conductive surface and a second wire coupled to the second conductive surface.

3. The apparatus as defined in claim 2, wherein the capacitance circuit is coupled to the first conductive surface via the first wire and the capacitance circuit is coupled to the second conductive surface via the second wire.

4. The apparatus as defined in claim 1, wherein the enclosure is a battery housing.

5. The apparatus as defined in claim 4, wherein an outer layer of the enclosure is an insulating material and the first conductive surface is an aluminum material adjacent to the insulating material.

6. The apparatus as defined in claim 4, wherein the second conductive surface is one of an anode or a cathode of the battery housing.

7. The apparatus as defined in claim 4, wherein the battery includes two or more active layers, respective ones of the active layers including:
an anode having a copper foil layer between a first graphite layer and a second graphite layer; and
a cathode separated from the anode with a separator, the cathode having an aluminum foil layer between a first active material and a second active material.

8. The apparatus as defined in claim 4, wherein the battery includes stacked anode layers and cathode layers.

9. The apparatus as defined in claim 4, wherein the battery includes rolled anode layers and cathode layers.

10. The apparatus as defined in claim 1, wherein the second conductive surface is one of a battery anode or a battery cathode.

11. The apparatus as defined in claim 10, wherein the third conductive surface is the other one of the battery anode or the battery cathode.

12. An apparatus to detect battery failure, comprising:
a housing including an insulating outer surface and a first conductive inner surface, the housing surrounding the battery;
a second conductive surface located a first distance from the enclosure;
means for capacitance measurement coupled to the first conductive surface and the second conductive surface; and
means for charge control to adjust an input charge value to the second conductive surface and a third conductive surface based on an output value of the means for capacitance measurement.

13. The apparatus as defined in claim 12, further including a first conductive lead coupled to the first conductive inner surface and a second conductive lead coupled to the second conductive surface.

14. The apparatus as defined in claim 13, wherein the means for capacitance measurement is:
coupled to the first conductive inner surface with the first conductive lead; and
coupled to the second conductive surface with the second conductive lead.

15. The apparatus as defined in claim 13, wherein the first conductive lead and the second conductive lead are wires.

16. The apparatus as defined in claim 12, wherein the means for capacitance measurement is to measure a capacitance value between the first conductive inner surface and the second conductive surface.

17. The apparatus as defined in claim 16, wherein the second conductive surface is at least one of an anode or a cathode of the battery.

18. A method to detect outgassing of a battery, comprising:
measuring a capacitance value between a first conductive battery surface and a second conductive battery surface;
comparing the capacitance value to a capacitance threshold value; and
controlling a charge input signal to the battery based on a magnitude difference between the capacitance value and the capacitance threshold value.

19. The method as defined in claim 18, wherein the first conductive battery surface is a conductive housing of the battery and the second conductive battery surface is one of an anode of the battery or a cathode of the battery.

20. The method as defined in claim 19, further including determining whether the capacitance threshold value satisfies a permissive charge condition or a prohibit charge condition.
